(19) United States
(12) Patent Application Publication
(10) Pub. No.: US 2018/0081215 A1
(43) Pub. Date: Mar. 22, 2018

(54) THIN-FILM TRANSISTOR, MANUFACTURE METHOD OF THIN-FILM TRANSISTOR, AND LIQUID CRYSTAL DISPLALY PANE

(71) Applicant: Shenzhen China Star Optoelectronics Technology Co. Ltd., Shenzhen, Guangdong (CN)

(72) Inventors: Shuli ZHAO, Shenzhen, Guangdong (CN); Macai LU, Shenzhen, Guangdong (CN)

(73) Assignee: Shenzhen China Star Optoelectronics Technology Co. Ltd., Shenzhen, Guangdong (CN)

(21) Appl. No.: 15/101,006

(22) PCT Filed: Apr. 14, 2016
(86) PCT No.: PCT/CN2016/079272

§ 371 Date: Jun. 2, 2016

(30) Foreign Application Priority Data
Mar. 28, 2016 (CN) 201610182408.4

(51) Int. Cl. G02F 1/1368; H01L 27/12; H01L 29/786; H01L 29/66; G02F 1/1343; H01L 29/417

(52) U.S. Cl. CPC G02F 1/1368; H01L 27/1288; H01L 29/7869; G02F 2001/136231; H01L 27/1225; G02F 1/134309; H01L 29/41733; H01L 29/66969

(57) ABSTRACT

A thin-film transistor includes a base plate; a gate zone arranged on a surface of the base plate; an insulation layer covering the gate zone; a first conductive section arranged on a surface of the insulation layer that is distant from the gate zone; a second conductive section arranged on the surface of the insulation layer and spaced from the first conductive section; a source zone arranged on a surface of the first conductive section that is distant from the insulation layer; a drain zone arranged on a surface of the second conductive section that is distant from the insulation layer; an active layer arranged on the surface of the insulation layer and having two ends respectively and electrically connected to the source zone and the drain zone; and a passivation layer covering the source zone, the drain zone and the active layer.

### CROSS REFERENCE TO RELATED APPLICATIONS

This application claims the priority of Chinese Patent Application No. 201610182408.4 filed on Mar. 28, 2016, titled “Thin-Film Transistor, Manufacture Method of Thin-Film Transistor, and Liquid Crystal Display Panel”, the disclosure of which is incorporated herein by reference in its entirety.

### BACKGROUND OF THE INVENTION

### 1. Field of the Invention

The present invention relates to the field of display, and more particularly to a thin-film transistor (TFT), a manufacture method of a thin-film transistor, and a liquid crystal display panel.

### 2. The Related Arts

Liquid crystal display devices, such as a liquid crystal display (LCD), are commonly used electronic devices, which possesses advantages including low power consumption, reduced size, and light weight, and have widely attracted the attention of users. A liquid crystal display generally comprises an array substrate. The array substrate comprises a plurality of thin-film transistors (TFTs) arranged in an array. The quality of the TFTs directly affects the quality of a liquid crystal display panel. Conventional ways for manufacturing TFTs generally involve six masks. The six masks that are necessary for the manufacture of the TFTs are briefly discussed as follows. The first mask is used to form a gate zone; the second mask is used to form an active layer; the third mask is used to form a etch stop layer; the fourth mask is used to form a source zone and a drain zone; the fifth mask is used to form a contact hole for exposing a portion of the drain zone; and the sixth mask is used to form a pixel electrode to allow the pixel electrode to electrically connect, via the contact hole, to the drain zone. It is apparent that heretofore, the number of mask operations involved in the manufacture methods of TFTs is relatively high and the process is thus complicated.

### SUMMARY OF THE INVENTION

The present invention provides a thin-film transistor. The thin-film transistor comprises:

a base plate;

a gate zone, which is arranged on a surface of the base plate;

an insulation layer, which is set on and covers the gate zone;

a first conductive section, which is arranged on a surface of the insulation layer that is distant from the gate zone;

a second conductive section, which is arranged on the surface of the insulation layer that is distant from the gate zone, the second conductive section and the first conductive section being spaced from each other;

a source zone, which is arranged on a surface of the first conductive section that is distant from the insulation layer;

a drain zone, which arranged on a surface of the second conductive section that is distant from the insulation layer;

an active layer, which is arranged on the surface of the insulation layer that is distant from the gate zone, the active layer having two opposite ends that are respectively and electrically connected to the source zone and the drain zone; and

a passivation layer, which is set on and covers the source zone, the drain zone, and the active layer.

In the above thin-film transistor, the thin-film transistor further comprises a pixel electrode, which arranged on a surface of the second conductive section that is distant from the insulation layer. The pixel electrode and the drain zone are arranged on the same layer and the pixel electrode and the drain zone are electrically connected.

In the above thin-film transistor, the pixel electrode and the drain zone are integrated as a unitary structure.

In the above thin-film transistor, the active layer comprises a metal oxide semiconductor layer.

In the above thin-film transistor, the active layer and the first and second conductive sections are arranged on the same layer.

In the above thin-film transistor, the gate zone comprises a first face, a second face, and a third face; the first face is in contact engagement with the base plate; the second face and the third face are opposite to each other and the second face and the third face are both in connection with the first face; the second face is arranged closer to the source zone than the third face; the third face is arranged closer to the drain zone than the second face; the second face is substantially coplanar with an end of the active layer that faces the source zone; and the third face is substantially coplanar with an end of the active layer that faces the drain zone.

The present invention also provides a manufacture method of a thin-film transistor. The manufacture method of a thin-film transistor comprises:

providing a base plate, wherein the base plate comprises a first surface and a second surface that are opposite to each other;

depositing a first metal layer on the first surface and patterning the first metal layer to form a gate zone;

forming an insulation layer on the gate zone to cover the gate zone;

depositing a transparent oxide semiconductor layer on a surface of the insulation layer that is distant from the gate zone;

forming a first photoresist layer to cover the transparent oxide semiconductor layer;

using the gate zone as a mask to subject the first photoresist layer to exposure from the second surface so as to remove a portion of the first photoresist layer that is not shielded by the gate zone and preserve a portion of the first photoresist layer that is shielded by the gate zone so as to form a first photoresist pattern corresponding to the gate zone;

using the first photoresist pattern as a mask to conduct ion injection or ultraviolet light irradiation on a portion of the transparent oxide semiconductor layer that is not shielded by the first photoresist pattern so as to form a first conductive section and a second conductive section, a portion of the transparent oxide semiconductor layer that is not shielded by the first photoresist pattern being an active layer;

depositing a transparent conductive oxide film and removing the first photoresist pattern;

depositing a second photoresist layer on the transparent conductive oxide film;

patterning the second photoresist layer to define a source zone that is arranged on a surface of the first conductive section that is distant from the insulation layer and a drain zone that is arranged on a surface of the second conductive section that is distant from the insulation layer removing the second photoresist layer; and

forming a passivation layer to cover the source zone, the drain zone, and the active layer.

In the above manufacture method of a thin-film transistor, the step of “patterning the second photoresist layer to define a source zone that is arranged on a surface of the first conductive section that is distant from the insulation layer and a drain zone that is arranged on a surface of the second conductive section that is distant from the insulation layer 130 removing the second photoresist layer” comprises:

pattering the second photoresist layer to define the source zone that is arranged on the surface of the first conductive section that is distant from the insulation layer, the drain zone that is arranged on the surface of the second conductive section that is distant from the insulation layer, and a pixel electrode that is arranged on the surface of the second conductive section that is distant from the insulation layer and on the same layer as the drain zone and is electrically connected to the drain zone.

In the above manufacture method of a thin-film transistor, the ion injection comprises hydrogen ion injection.

The present invention also provides a liquid crystal display panel. The liquid crystal display panel comprises the thin-film transistor described above.

Compared to the prior art, the present invention provides a manufacture method of a thin-film transistor that uses two mask based operations to form a thin-film transistor, so that the number of using masks is reduced and the process of forming the thin-film transistor is simplified. Further, the present invention provides a thin-film transistor that comprises a source zone that is set in contact engagement with an active layer via a first conductive section so as to reduce the contact resistance between the source zone and the active layer and improve contact property between the source zone and the active layer; in addition, thin-film transistor of the present invention comprises a drain zone that is set in contact engagement with the active layer through a second conductive section so as to reduce the contact resistance between the drain zone and the active layer and improve contact property between the drain zone and the active layer.

### BRIEF DESCRIPTION OF THE DRAWINGS

To more clearly explain the technical solution proposed in an embodiment of the present invention and that of the prior art, a brief description of the drawings that are necessary for describing embodiments is given as follows. It is obvious that the drawings that will be described below show only some embodiments. For those having ordinary skills of the art, other drawings may also be readily available from these attached drawings without the expense of creative effort and endeavor.

FIG. 1 is a cross-sectional view showing a thin-film transistor according to a preferred embodiment of the present invention;

FIG. 2 is a schematic view illustrating a liquid crystal display panel according to a preferred embodiment of the present invention; and

FIG. 3 is a flow chart illustrating a manufacture method of a thin-film transistor according to a preferred embodiment of the present invention.

### DETAILED DESCRIPTION OF THE PREFERRED EMBODIMENTS

A clear and complete description will be given to a technical solution of embodiments of the present invention with reference to the attached drawings of the embodiments of the present invention. However, the embodiments so described are only some, but not all, of the embodiments of the present invention. Other embodiments that are available to those having ordinary skills of the art without the expense of creative effort and endeavor are considered belonging to the scope of protection of the present invention.

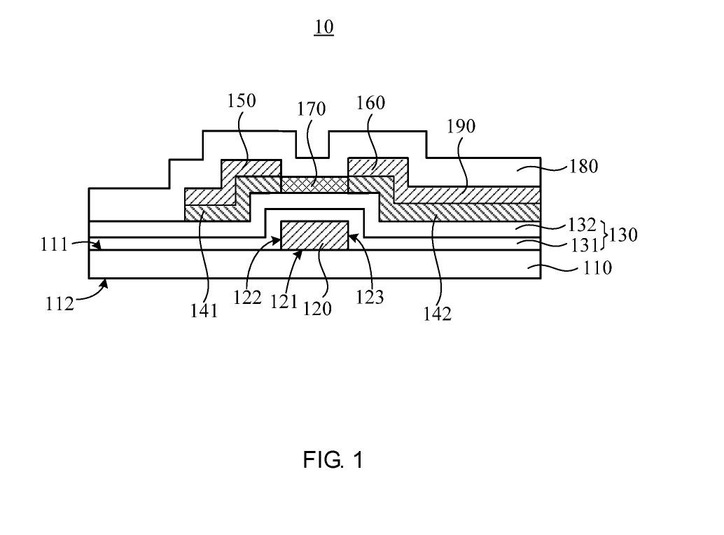

Referring to FIG. 1, FIG. 1 is a cross-sectional view showing a thin-film transistor according to a preferred embodiment of the present invention. The thin-film transistor 10 comprises a base plate 110 and a gate zone 120, an insulation layer 130, a first conductive section 141, a second conductive section 142, a source zone 150, a drain zone 160, an active layer 170, and a passivation layer 180 that are arranged on the same of the base plate 110. The gate zone 120 is arranged on a surface of the base plate 110; the insulation layer 130 covers the gate zone 120; the first conductive section 141 is arranged on a surface of the insulation layer 130 that is distant from the gate zone 120; the second conductive section 142 is arranged on a surface of the insulation layer 130 that is distant from the gate zone 120 and the second conductive section 142 and the first conductive section 141 are spaced from each other; the source zone 150 is arranged on a surface of the first conductive section 141 that is distant from the insulation layer 130; the drain zone 160 is arranged on a surface of the second conductive section 142 that is distant from the insulation layer 130; the active layer 170 is arranged on the surface of the insulation layer 130 that is distant from the gate zone 120 and the active layer 170 has two opposite ends that are respectively and electrically connected to the source zone 150 and the drain zone 160; and the passivation layer 180 covers the source zone 150, the drain zone 160, and the active layer 170.

In the instant embodiment, the base plate 110 is an insulation backing having light transmittance that is greater than predetermined light transmittance for external light. The predetermined light transmittance can be, but not limited to, 90%. The base plate 110 is made of a material that comprises one or multiple ones of electrical insulation materials including quartz, mica, aluminum oxide, and transparent plastics. The base plate 110 being an insulation backing helps reduces high frequency loss of the base plate 110.

The gate zone 120 comprises a first face 121, a second face 122, and a third face 123. The first face 121 is in contact engagement with the base plate 110; the second face 122 and the third face 123 are opposite to each other; and the second face 122 and the third face 123 are both in connection with the first face 121. The second face 122 is arranged closer to the source zone 150 than the third face 123; and the third face 123 is arranged closer to the drain zone 160 than the second face 122. The second face 122 is coplanar with an end of the active layer 170 that faces the source zone 150; and the third face 123 is coplanar with an end of the active layer 170 that faces the drain zone 160.

Due to the second face 122 of the gate zone 120 being coplanar with the end of the active layer 170 that faces the source zone 150 and the third face 123 of the gate zone 120 being coplanar with the end of the active layer 170 that faces the drain zone 160, there is no insulation medium sidewall existing between the gate zone 120 and the source zone 150 and there is also insulation medium sidewall existing between the gate zone 120 and the drain zone 160 and thus, parasitic resistance that is potentially present in the thin-film transistor 10 can be suppressed. Further, due to the second face 122 of the gate zone 120 being coplanar with the end of the active layer 170 that faces the source zone 150 and the third face 123 of the gate zone 120 being coplanar with the end of the active layer 170 that faces the drain zone 160, there is no overlapping between the gate zone 120 and the source zone 150 and there is also no overlapping between the gate zone 120 and the drain zone 160 and thus, parasitic capacitance between the gate zone 120 and the source zone 150 is reduced and parasitic capacitance between the gate zone 120 and the drain zone 160 is reduced.

Further, in the present invention, the gate zone 120, the source zone 150, and the drain zone 160 of the thin-film transistor 10 can be made thicker, but not significantly increasing the parasitic capacitance between the gate zone 120 and the gate zone 150 and the parasitic capacitance between the gate zone 120 and the drain zone 160. The thicker gate zone 120, the thicker source zone 150, and the thicker drain zone 160 help reduce the electrical resistance of these electrode zones and also suppress parasitic resistance induced in these electrode zones. Preferably, the gate zone 120 has a thickness that is 1500-6000 Å; the source zone 150 has a thickness that is 2000-5000 Å; and the drain zone 160 has a thickness that is 2000-5000 Å.

The gate zone 120 blocks ultraviolet light that transmits through the base plate 110 so that the ultraviolet light that transmits through the base plate 110 is prevented from transmitting the gate zone 120. It is appreciated that when the ultraviolet light that transmits through the base plate 110 is allowed to transmit the gate zone 120 with light transmittance thereof being less than a preset threshold level (such as 5%), it is also considered that the ultraviolet light that passes through the base plate 110 does not transmit through the gate zone 120. The gate zone 120 is made of a material comprising, but not limited to, one or multiple ones of metallic materials including Al, Mo, Cu, Ag, Cr, Ti, AlNi, and MoTi. The gate zone 120 has a thickness that is 1500-6000 Å.

The insulation layer 130 comprises a first sub insulation layer 131 and a second sub insulation layer 132. The first sub insulation layer 131 is set on and covers the gate zone 120, and the second sub insulation layer 132 is set on and covers the first sub insulation layer 131. The first sub insulation layer 131 comprises a silicon nitride (SiNx) material; and the second sub insulation layer 132 comprises a silicon oxide (SiOx) material. The first sub insulation layer 131 that comprises a silicon nitride material, may generate, during the manufacture of the silicon nitride material, hydrogen (H) element that can be used to repair the active layer 180 so as to improve electrical properties of the active layer 180. The second sub insulation layer 132 helps improve stresses induced in the first conductive section 141, the second conductive section 142, and the active layer 180 that are arranged on the second sub insulation layer 132 to prevent detachment of the first conductive section 141, the second conductive section 142, and the active layer 180. The insulation layer 130 may have a thickness that is 1500-4000 Å.

The first conductive section 141 and the second conductive section 142 can be formed by applying treatments such as ultraviolet light irradiation or ion injection to a transparent oxide semiconductor layer. The ion injection used can be hydrogen ion injection. The transparent oxide semiconductor layer may comprise, but not limited to, one or multiple ones of the following materials: ZnO based transparent oxide semiconductor materials, SnO₂ based transparent oxide semiconductor materials, and In₂O₃ based transparent oxide semiconductor materials. For example, the transparent oxide semiconductor layer can be indium gallium zinc oxide (IGZO).

The first conductive section 141 helps improve contact property between the source zone 150 and the active layer 170. The second conductive section 142 helps improve contact property between the drain zone 160 and the active layer 170.

Materials that make the source zone 150 and the drain zone 160 can be transparent conductive oxide films and the transparent conductive oxide films comprise, but not limited to, indium tin oxide (ITO), indium zinc oxide (IZO), fluorine doped tin oxide (SnO2:F, FTO), and aluminum doped zinc oxide (ZnO:Al, AZO).

The active layer 170 is also referred to as a channel layer, and preferably, the active layer 170 comprises a metal oxide semiconductor layer. The metal oxide semiconductor layer may comprise, but not limited to, one or multiple ones of the following materials: ZnO based transparent oxide semiconductor materials, SnO₂ based transparent oxide semiconductor materials, and In₂O₃ based transparent oxide semiconductor materials. For example, the active layer 170 can be indium gallium zinc oxide (IGZO).

Preferably, the active layer 170 and the first conductive section 141 and the second conductive section 142 are set up on the same layer.

The passivation layer 180 has a thickness that is 1500-4000 Å. The passivation layer 180 may comprise, but not limited to, a silicon nitride (SiNx) material, a silicon oxide (SiOx) material, or a composite layer of a silicon oxide material and a silicon nitride material.

The thin-film transistor 10 further comprises a pixel electrode 190. The pixel electrode 190 is arranged on a surface of the second conductive section 142 that is distant from the insulation layer 130. The pixel electrode 190 and the drain zone 160 are set up on the same layer and the pixel electrode 190 and the drain zone 160 are electrically connected. Preferably, the pixel electrode 190 and the drain zone 160 are integrated as a unitary structure. The pixel electrode 190 has a thickness that is 300-1000 Å. The pixel electrode 190 may comprise, but not limited to, indium tin oxide (ITO).

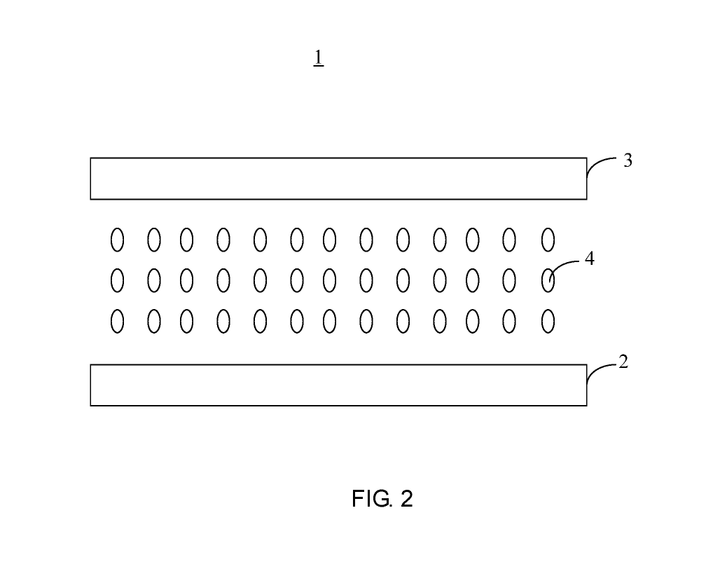

The present invention also provides a liquid crystal display panel. Referring to FIG. 2, FIG. 2 is a schematic view illustrating a liquid crystal display panel according to a preferred embodiment of the present invention. The liquid crystal display panel 1 according to the present invention comprises an array substrate 2, a color filter substrate 3, and a liquid crystal layer 4. The array substrate 2 and the color filter substrate 3 are arranged opposite to and spaced from each other. The liquid crystal layer 4 is sandwiched between the array substrate 2 and the color filter substrate 3. The array substrate 2 comprises a plurality of thin-film transistors 10 arranged in an array. Details of the thin-film transistors 10 may be referred to the description given above and repeated description will be omitted here.

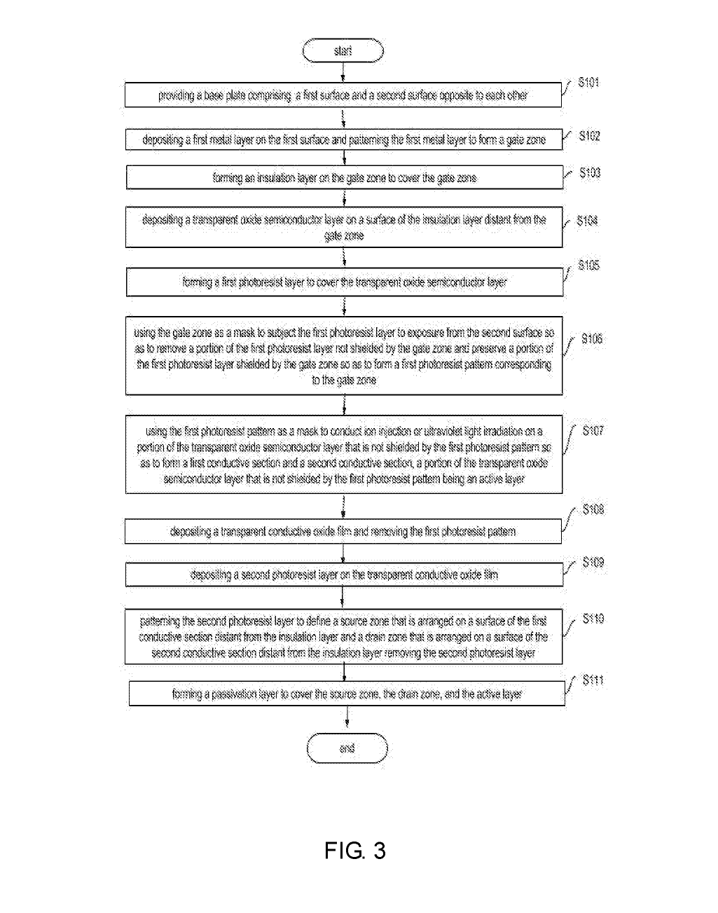

In the following, a description will be given, with reference to FIG. 1 and the description provided associated with FIG. 1, for illustrating a manufacture method of a thin-film transistor according to the present invention. Reference being also had to FIG. 3, FIG. 3 is a flow chart illustrating a manufacture method of a thin-film transistor according to a preferred embodiment of the present invention. The manufacture method of a thin-film transistor comprises, but not limited to, the following steps.

S101: providing a base plate 110, wherein the base plate 110 comprises a first surface 111 and a second surface 112 that are opposite to each other. In the instant embodiment, the base plate 110 is an insulation backing having light transmittance that is greater than predetermined light transmittance for external light. The predetermined light transmittance can be, but not limited to, 90%. The base plate 110 is made of a material that comprises one or multiple ones of electrical insulation materials including quartz, mica, aluminum oxide, and transparent plastics. The base plate 110 being an insulation backing helps reduces high frequency loss of the base plate 110.

S102: depositing a first metal layer on the first surface 111 and patterning the first metal layer to form a gate zone 120. Specifically, the first metal layer is deposited on the first surface 111 of the base plate 110 and is subjected to etching by using a first mask to form the gate zone 120. The first metal layer blocks ultraviolet light that transmits through the base plate 110 so that the ultraviolet light that transmits through the base plate 110 is prevented from transmitting the gate zone 120. It is appreciated that when the ultraviolet light that transmits through the base plate 110 is allowed to transmit the gate zone 120 with light transmittance thereof being less than a preset threshold level (such as 5%), it is also considered that the ultraviolet light that passes through the base plate 110 does not transmit through the gate zone 120. The first metal layer is made of a material comprising, but not limited to, one or multiple ones of metallic materials including Al, Mo, Cu, Ag, Cr, Ti, AlNi, and MoTi.

S103: forming an insulation layer 130 on the gate zone 120 to cover the gate zone 120. The insulation layer 130 comprises, but no limited to, a silicon nitride (SiNx) material or a silicon oxide (SiOx) material.

S104: depositing a transparent oxide semiconductor layer on a surface of the insulation layer 130 that is distant from the gate zone 120. The transparent oxide semiconductor layer may comprise, but not limited to, one or multiple ones of the following materials: ZnO based transparent oxide semiconductor materials, SnO₂ based transparent oxide semiconductor materials, and In₂O₃ based transparent oxide semiconductor materials. For example, the transparent oxide semiconductor layer can be indium gallium zinc oxide (IGZO).

S105: forming a first photoresist layer to cover the transparent oxide semiconductor layer.

S106: using the gate zone 120 as a mask to subject the first photoresist layer to exposure from the second surface 112 so as to remove a portion of the first photoresist layer that is not shielded by the gate zone 120 and preserve a portion of the first photoresist layer that is shielded by the gate zone so as to form a first photoresist pattern corresponding to the gate zone.

S107: using the first photoresist pattern as a mask to conduct ion injection or ultraviolet light irradiation on a portion of the transparent oxide semiconductor layer that is not shielded by the first photoresist pattern so as to form a first conductive section 141 and a second conductive section 142, a portion of the transparent oxide semiconductor layer that is not shielded by the first photoresist pattern being an active layer 170. In the instant embodiment, the ion injection conducted is hydrogen ion injection.

Tests reveal that the transparent oxide material layer would exhibit significant variation in respect of electrical property thereof with irradiation of ultraviolet light for different periods of time and mobility and carrier concentration may get increased with extension of irradiation time of ultraviolet light, meaning excellent electrical conductivity is obtained. Taking the transparent oxide material layer being IGZO as an example, tests indicate for a period of four (5) hours of irradiation of ultraviolet light, a portion of the transparent oxide material layer that is so irradiated shows resistivity of 4.6*10⁻³, hall mobility being 14.6 cm²/V, and carrier concentration being 1.6*10¹² cm², and with an aging test lasting for a given period of time (which is four weeks in this example), the transparent oxide material layer so irradiated with ultraviolet light show barely no variation in respect of electrical conductivity, mobility, and carrier concentration.

S108: depositing a transparent conductive oxide film and removing the first photoresist pattern.

S109: depositing a second photoresist layer on the transparent conductive oxide film.

S110: patterning the second photoresist layer to define a source zone 150 that is arranged on a surface of the first conductive section 141 that is distant from the insulation layer 130 and a drain zone 160 that is arranged on a surface of the second conductive section 142 that is distant from the insulation layer 130 and removing the second photoresist layer. Specifically, step S110 comprises: pattering the second photoresist layer to define the source zone 150 that is arranged on the surface of the first conductive section 141 that is distant from the insulation layer 130, the drain zone 160 that is arranged on the surface of the second conductive section 142 that is distant from the insulation layer 130, and a pixel electrode 190 that is arranged on the surface of the second conductive section 142 that is distant from the insulation layer 130 and on the same layer as the drain zone 160 and is electrically connected to the drain zone 160. In the step of forming the source zone 150, the drain zone 160 (and the pixel electrode 190) uses a second mask.

S111: forming a passivation layer 180 to cover the source zone 150, the drain zone 160, and the active layer 170.

Compared to the prior art, the present invention provides a manufacture method of a thin-film transistor that uses two mask based operations to form a thin-film transistor, so that the number of using masks is reduced and the process of forming the thin-film transistor is simplified. Further, the present invention provides a thin-film transistor 10 that comprises a source zone 150 that is set in contact engagement with an active layer 170 via a first conductive section 141 so as to reduce the contact resistance between the source zone 150 and the active layer 170 and improve contact property between the source zone 150 and the active layer 170; in addition, thin-film transistor 10 of the present invention comprises a drain zone 160 that is set in contact engagement with the active layer 170 through a second conductive section 142 so as to reduce the contact resistance between the drain zone 160 and the active layer 170 and improve contact property between the drain zone 160 and the active layer 170.

The present invention has been described with reference to the preferred embodiments. However, it is noted that those skilled in the art would appreciates that various improvements and modifications are still available without departing from the scope of the present invention and such improvements and modifications are considered within the scope of protection of the present invention.

What is claimed is:

1. A thin-film transistor, comprising:
a base plate;
a gate zone, which is arranged on a surface of the base plate;
an insulation layer, which is set on and covers the gate zone;
a first conductive section, which is arranged on a surface of the insulation layer that is distant from the gate zone;
a second conductive section, which is arranged on the surface of the insulation layer that is distant from the gate zone, the second conductive section and the first conductive section being spaced from each other;
a source zone, which is arranged on a surface of the first conductive section that is distant from the insulation layer;
a drain zone, which arranged on a surface of the second conductive section that is distant from the insulation layer;
an active layer, which is arranged on the surface of the insulation layer that is distant from the gate zone, the active layer having two opposite ends that are respectively and electrically connected to the source zone and the drain zone; and
a passivation layer, which is set on and covers the source zone, the drain zone, and the active layer.

2. The thin-film transistor as claimed in claim 1, wherein the thin-film transistor further comprises a pixel electrode, which arranged on a surface of the second conductive section that is distant from the insulation layer, the pixel electrode and the drain zone being arranged on the same layer, the pixel electrode and the drain zone being electrically connected.

3. The thin-film transistor as claimed in claim 2, wherein the pixel electrode and the drain zone are integrated as a unitary structure.

4. The thin-film transistor as claimed in claim 1, wherein the active layer comprises a metal oxide semiconductor layer.

5. The thin-film transistor as claimed in claim 1, wherein the active layer and the first and second conductive sections are arranged on the same layer.

6. The thin-film transistor as claimed in claim 1, wherein the gate zone comprises a first face, a second face, and a third face; the first face is in contact engagement with the base plate; the second face and the third face are opposite to each other and the second face and the third face are both in connection with the first face; the second face is arranged closer to the source zone than the third face; the third face is arranged closer to the drain zone than the second face; the second face is substantially coplanar with an end of the active layer that faces the source zone; and the third face is substantially coplanar with an end of the active layer that faces the drain zone.

7. A manufacture method of a thin-film transistor, comprising:
providing a base plate, wherein the base plate comprises a first surface and a second surface that are opposite to each other;
depositing a first metal layer on the first surface and patterning the first metal layer to form a gate zone;
forming an insulation layer on the gate zone to cover the gate zone;
depositing a transparent oxide semiconductor layer on a surface of the insulation layer that is distant from the gate zone;
forming a first photoresist layer to cover the transparent oxide semiconductor layer;
using the gate zone as a mask to subject the first photoresist layer to exposure from the second surface so as to remove a portion of the first photoresist layer that is not shielded by the gate zone and preserve a portion of the first photoresist layer that is shielded by the gate zone so as to form a first photoresist pattern corresponding to the gate zone;
using the first photoresist pattern as a mask to conduct ion injection or ultraviolet light irradiation on a portion of the transparent oxide semiconductor layer that is not shielded by the first photoresist pattern so as to form a first conductive section and a second conductive section, a portion of the transparent oxide semiconductor layer that is not shielded by the first photoresist pattern being an active layer;
depositing a transparent conductive oxide film and removing the first photoresist pattern;
depositing a second photoresist layer on the transparent conductive oxide film;
patterning the second photoresist layer to define a source zone that is arranged on a surface of the first conductive section that is distant from the insulation layer and a drain zone that is arranged on a surface of the second conductive section that is distant from the insulation layer removing the second photoresist layer; and
forming a passivation layer to cover the source zone, the drain zone, and the active layer.

8. The manufacture method of a thin-film transistor as claimed in claim 7, wherein the step of “patterning the second photoresist layer to define a source zone that is arranged on a surface of the first conductive section that is distant from the insulation layer and a drain zone that is arranged on a surface of the second conductive section that is distant from the insulation layer 130 removing the second photoresist layer” comprises:
pattering the second photoresist layer to define the source zone that is arranged on the surface of the first conductive section that is distant from the insulation layer, the drain zone that is arranged on the surface of the second conductive section that is distant from the insulation layer, and a pixel electrode that is arranged on the surface of the second conductive section that is distant from the insulation layer and on the same layer as the drain zone and is electrically connected to the drain zone.

9. The manufacture method of a thin-film transistor as claimed in claim 7, wherein the ion injection comprises hydrogen ion injection.

10. A liquid crystal display panel, comprising a thin-film transistor, the thin-film transistor comprising:
a base plate;
a gate zone, which is arranged on a surface of the base plate;
an insulation layer, which is set on and covers the gate zone;
a first conductive section, which is arranged on a surface of the insulation layer that is distant from the gate zone;
a second conductive section, which is arranged on the surface of the insulation layer that is distant from the gate zone, the second conductive section and the first conductive section being spaced from each other;
a source zone, which is arranged on a surface of the first conductive section that is distant from the insulation layer;
a drain zone, which arranged on a surface of the second conductive section that is distant from the insulation layer;
an active layer, which is arranged on the surface of the insulation layer that is distant from the gate zone, the active layer having two opposite ends that are respectively and electrically connected to the source zone and the drain zone; and
a passivation layer, which is set on and covers the source zone, the drain zone, and the active layer.

11. The liquid crystal display panel as claimed in claim 10, wherein the thin-film transistor further comprises a pixel electrode, which arranged on a surface of the second conductive section that is distant from the insulation layer, the pixel electrode and the drain zone being arranged on the same layer, the pixel electrode and the drain zone being electrically connected.

12. The liquid crystal display panel as claimed in claim 11, wherein the pixel electrode and the drain zone are integrated as a unitary structure.

13. The liquid crystal display panel as claimed in claim 10, wherein the active layer comprises a metal oxide semiconductor layer.

14. The liquid crystal display panel as claimed in claim 10, wherein the active layer and the first and second conductive sections are arranged on the same layer.

15. The liquid crystal display panel as claimed in claim 10, wherein the gate zone comprises a first face, a second face, and a third face; the first face is in contact engagement with the base plate; the second face and the third face are opposite to each other and the second face and the third face are both in connection with the first face; the second face is arranged closer to the source zone than the third face; the third face is arranged closer to the drain zone than the second face; the second face is substantially coplanar with an end of the active layer that faces the source zone; and the third face is substantially coplanar with an end of the active layer that faces the drain zone.
